(19) United States
(12) Patent Application Publication
(10) Pub. No.: US 2012/0051067 A1
(43) Pub. Date: Mar. 1, 2012

(54) LIGHTING DISPLAY AND METHOD OF MANUFACTURING SAME

(75) Inventor: Patrick M. Murray, Bloomfield Township, MI (US)

(73) Assignee: Key Plastics L.L.C., Northville, MI (US)

(21) Appl. No.: 13/196,243

(22) Filed: Aug. 2, 2011

Related U.S. Application Data
(60) Provisional application No. 61/376,415, filed on Aug. 24, 2010.

(51) Int. Cl. F21V 3/00; H05K 13/00

(52) U.S. Cl. 362/311.02; 29/592.1

(57) ABSTRACT

A lighting display includes a light-emitting member such as an organic light emitting diode (OLED) member activatable to emit light and a substrate adjacent the OLED member forming an integral, multi-dimensional lighting display. A transparent member may be positioned so that the OLED member is between the transparent member and the substrate. The OLED member (or the transparent member, if one is provided), has an image on a surface such that the image is visible when the OLED member emits lights. A method of manufacturing the lighting display is also provided.

### CROSS-REFERENCE TO RELATED APPLICATIONS

This application claims the benefit of U.S. Provisional Application Ser. No. 61/376,415, filed Aug. 24, 2010, which is hereby incorporated by reference in its entirety.

### TECHNICAL FIELD

The invention relates to a lighting display and a method of producing the same.

### BACKGROUND

Many components of an automobile can be enhanced by the inclusion and integration of lighting for the purpose of conveying information (functional lighting) or providing light to improve visibility (task lighting) or for improving aesthetics (ambient lighting). Light sources are also used to display vehicle information such as radio, HVAC, cluster displays, video infotainment and entertainment, etc. Typically, flat or flexible light sources are framed by plastic components.

### SUMMARY

A lighting display is provided in which a source of light, such as an organic light-emitting diode (OLED) is integrated into surrounding components, such as a substrate and an optional transparent member, both of which may be injection molded plastic. The light source contains the same, or similar multi-directional surfaces as the surrounding plastic components, enabling improved performance and a consistent lighted appearance. The lighting display may be used in a variety of applications, such as a vehicle interior. As most automobile components are curved or contoured, it is an advantage to have a light-producing item which can be formed to the curve or contour of the component.

An organic light-emitting diode (OLED) is a light-producing item that can be manufactured as a flexible device and so can be formed into a component with multi-directional contour. The emissive layer of an OLED is a film of organic compounds that is activated to emit light by passing an electric current through it. This layer of organic semiconductor material is formed between two electrodes, one or both of which are transparent.

An OLED can be used as a functional light, task light, or ambient light or combination thereof. A flexible OLED also allows for generation of static graphic or ‘photographic’ (video or still) imagery to be displayed onto its surface. When integrated onto a multi-dimensional and multi-directional component, a multi-dimensional and multi-directional information display screen is created. This can be used to provide a vehicle human-machine interface (HMI) including switches and controls for diagnostic or vehicle performance information such as a speed, engine revolutions per minute, temperature, and battery state of charge in a cluster, a radio, a heat, ventilation and air conditioning (HVAC) system and a navigation system in a center stack display, or static or dynamic decorative surfaces.

The components of the lighting display can be injection and otherwise molded to form flat, multi-dimensional, or fully sculpted surfaces. It is expected to be a manufacturing advantage to integrate a light-emitting member into the molding process to improve intensity and consistency of emitted visible light, reduce the amount of energy or power required to produce the same visible luminosity as when lighting through a translucent component, and improve product life as the light-emitting source is encapsulated within a plastic component.

Alternatively, after the individual components of the lighting display are molded, a light-emitting member may be included as part of a layered assembly such as by encapsulating the light-emitting member behind or between a molded substrate and an A-surface treatment, such as a transparent film or layer, or as the A-surface treatment itself.

Specifically, a lighting display includes an OLED member activatable to emit light and a substrate adjacent the OLED member forming an integral, multi-dimensional lighting display. A transparent member may be positioned so that the OLED member is between the transparent member and the substrate. The OLED member (or the transparent member, if one is provided), has an image on a surface. The image is visible when the OLED member emits lights. A method of manufacturing the lighting display is also provided.

The above features and advantages and other features and advantages of the present invention are readily apparent from the following detailed description of the best modes for carrying out the invention when taken in connection with the accompanying drawings.

### BRIEF DESCRIPTION OF THE DRAWINGS

FIG. 1 is a schematic perspective view of a vehicle having a lighting display in an inactivated state;

FIG. 2 is a schematic perspective view of the vehicle of FIG. 1 with the lighting display activated, as indicated by dashes representing light;

FIG. 3 is a schematic perspective exploded view of an embodiment of a lighting display;

FIG. 4 is a schematic cross-sectional illustration of the lighting display of FIG. 3 taken at the lines 4-4 in FIG. 3;

FIG. 5 is a schematic perspective exploded view of an embodiment of a lighting display;

FIG. 6 is a schematic cross-sectional illustration of the lighting display of FIG. 5 taken at the lines 6-6 in FIG. 5;

FIG. 7 is a schematic perspective exploded view of an embodiment of a lighting display;

FIG. 8 is a schematic cross-sectional illustration of the lighting display of FIG. 7 taken at the lines 8-8 in FIG. 7;

FIG. 9 is a schematic perspective exploded view of an embodiment of a lighting display;

FIG. 10 is a schematic cross-sectional illustration of the lighting display of FIG. 9 taken at the lines 10-10 in FIG. 9;

FIG. 11A is a schematic perspective illustration of one embodiment of a lighting display;

FIG. 11B is a schematic perspective illustration of an opposing side of the lighting display of FIG. 11A; and

FIG. 12 is a flowchart of a method of manufacturing a lighting display.

### DETAILED DESCRIPTION

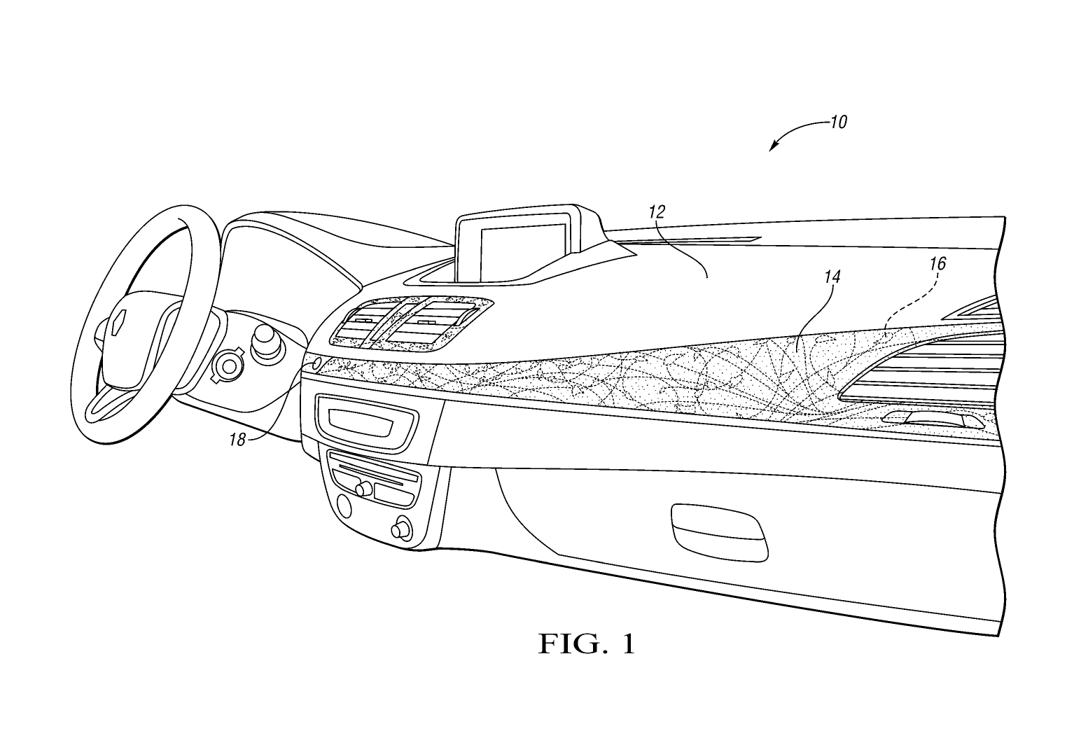

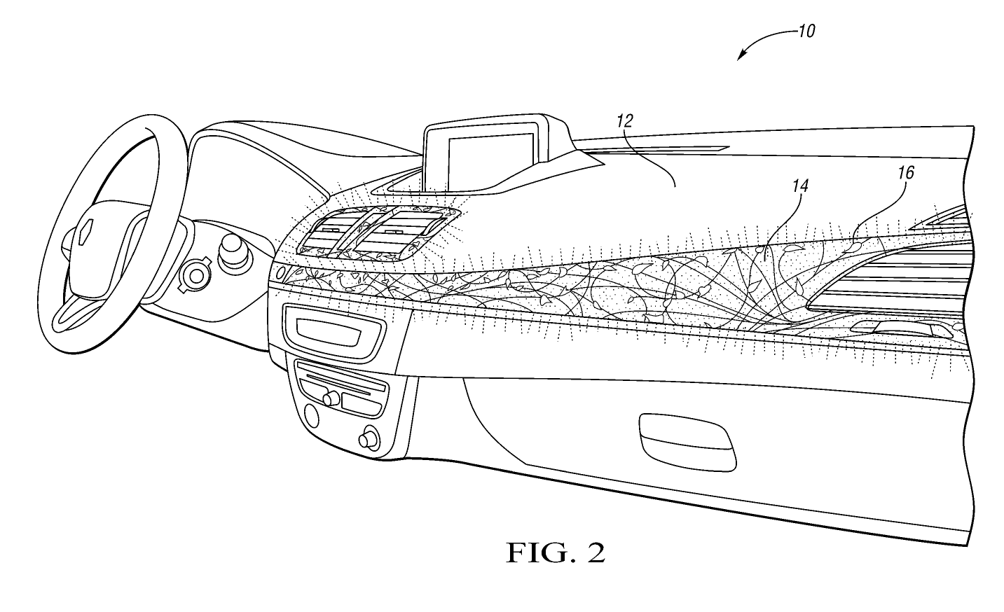

Referring to the drawings, wherein like reference numbers refer to like components throughout the several views, FIG. 1 shows a vehicle 10 having an instrument panel 12 that includes a multi-dimensional, curved and contoured lighting display 14. An image 16 is shown dynamically by pressing an operator input button 18 to activate an OLED member (discussed below) within the lighting display 10. Prior to activating the lighting display 14, the image 16 may be substantially hidden, and is therefore indicated with dashes in FIG. 1, so that the panel 12 appears substantially uniform. The image 16 is at least much less visible than when the lighting display 14 is activated. The image 16 is lighted in a dynamic manner, such as from left to right, so that a first portion of the image is lit before a second portion of the image is lit. Alternatively, the entire image 16 may be lighted at once. The image 16 is shown fully lighted in FIG. 2, as indicated by dashes representing light. Other input means may be used to trigger activation of the lighting display. Although shown as part of an instrument panel, the lighting display could be part of a different component, such as but not limited to a door, an overhead lighting component, or an exterior lighting component. Lighting displays as described herein may be used in a variety of applications, including nonautomotive applications.

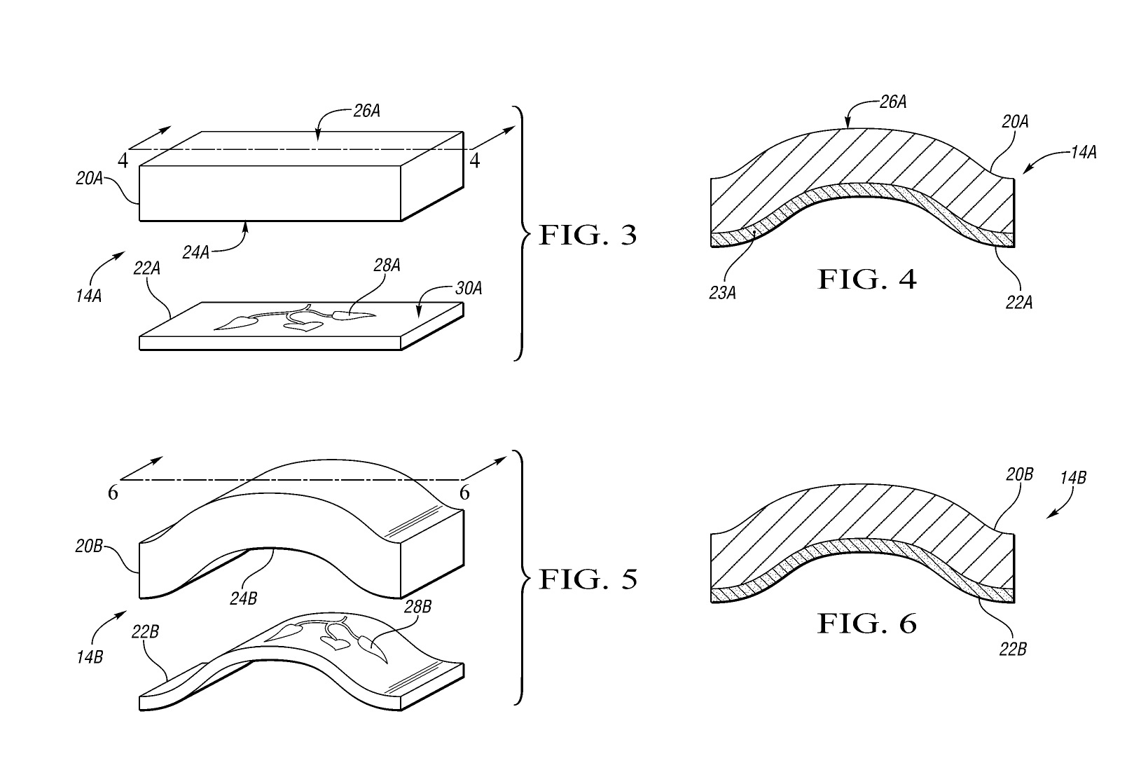

FIG. 3 shows another embodiment of a lighting display 14A. The lighting display 14A includes a substrate 20A and a lighting member 22A. The lighting member 22A may be an OLED member activatable to emit light. The substrate 20A serves to provide support and protect the lighting member 20A. In this embodiment, the substrate 20A is substantially transparent. The lighting member 22A is secured to an underside 24A (shown in FIG. 3) of the substrate 20A, as shown in FIG. 4. The underside 24A is also referred to as the “B” surface of the substrate 20A, as the opposing side 26A (referred to as the “A” surface) is the surface that will be the viewing surface of the lighting display 14A.

An image 28A is applied to the lighting member 22A. The image 28A may be applied by painting the surface 30A of the lighting member 22A that faces the underside 24A of the substrate 20A. Alternatively, the image 28A may be a graphic printed on the surface 30A. The image 28A shows light emitted from the transparent lighting member 22A when the lighting member 22A is activated, while the areas of the surface 30A surrounding the image 28A block light from being emitted from the lighting member 22A through those areas. Thus, only the image 28A appears to be lighted.

As shown in FIG. 4, the lighting member 22A and substrate 20A may be placed together in a common mold and then molded simultaneously to the multi-dimensional shape of FIG. 4. When the lighting member 22A is activated, the organic compounds 23A within the lighting member 22A emit light, and the image 28A will be visible through the surface 26A of the substrate 20A. Because the surface 30A of the lighting member 22A abuts and follows the surface 24A of the substrate 20A so that the adjacent surfaces 30A, 24A have common shapes, the consistency of the lighted appearance of the lighting display 14A is improved in comparison to lighting displays in which the distance of the light-emitting members from the viewing surface varies.

Referring to FIGS. 5 and 6, another embodiment of a lighting display 14B is shown that is alike in all aspects to the lighting display 14A except that the substrate 20B is molded in a separate mold from the lighting member 22B, prior to assembly, as shown in FIG. 5. The image 28B may be created in either of the alternate manners described with respect to image 28A. The preformed substrate 20B and lighting member 22B with multidimensional shapes are then operatively connected to one another to form the completed lighting display 14B.

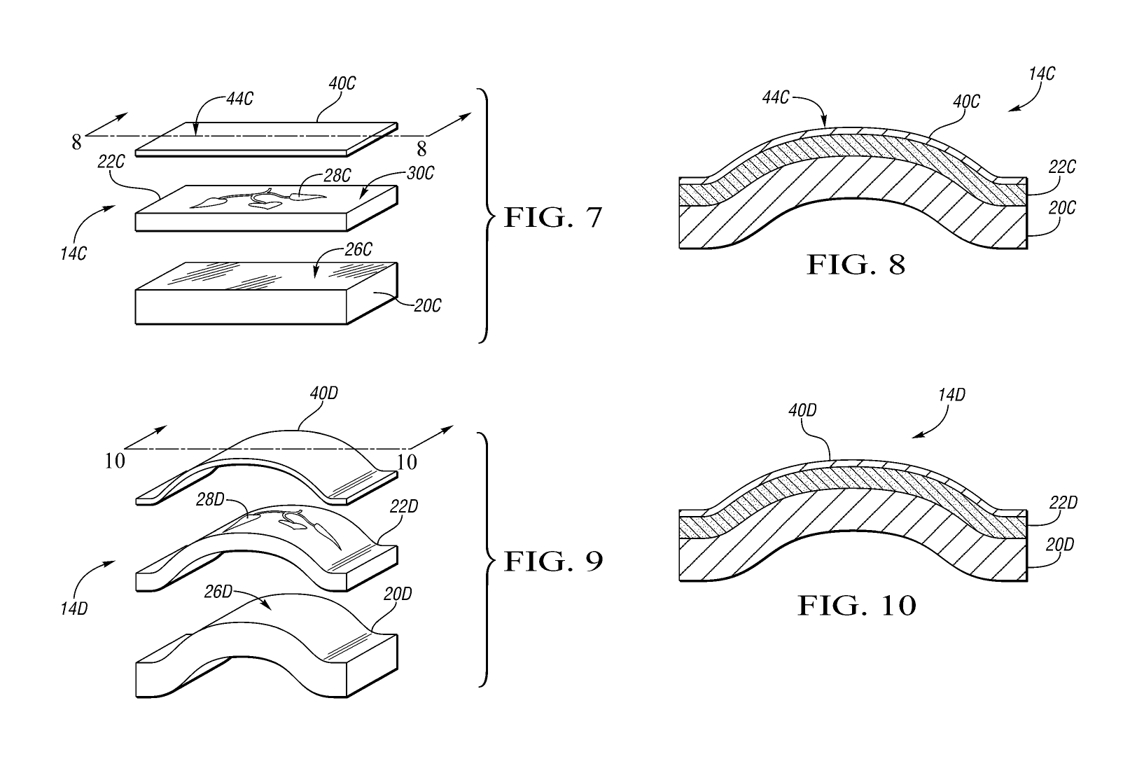

Referring to FIGS. 7 and 8, another lighting display 14C is shown having a lighting member 22C with an image 28C created by painting and laser etching the surface 30C or by printing the surface 30C, similarly as described with respect to FIG. 3. The lighting member 22C may be an OLED member as described above. The lighting member 22C is operatively connected to an “A” surface 26C of the substrate 20C. A transparent member 40C that may be a film and serves as a protective layer is applied to the lighting member 22C so that the lighting member 22C is sandwiched between the substrate 20C and the transparent member 40C. The substrate 20C may be substantially translucent, opaque or transparent.

As shown in FIG. 8, the transparent member 40C, the lighting member 22C and the substrate 20C are placed together in a common mold and then molded simultaneously to the multi-dimensional shape of FIG. 8. Because the transparent member 40C, lighting member 22C and substrate 20C are molded to have abutting surfaces with complementary shapes, the consistency of the light visible through the viewing surface 44C of the transparent member 40C is improved.

Referring to FIGS. 9 and 10, another embodiment of a lighting display 14D is shown that is alike in all aspects to the lighting display 14C except that the transparent member 40D and the substrate 20D are molded in separate molds than the lighting member 22D, prior to assembly, as shown in FIG. 10. The image 28D may be created in either of the alternate manners described with respect to image 28C. The transparent member 40D, preformed substrate 20D and lighting member 22D with multidimensional shapes are then operatively connected to one another to form the completed lighting display 14D.

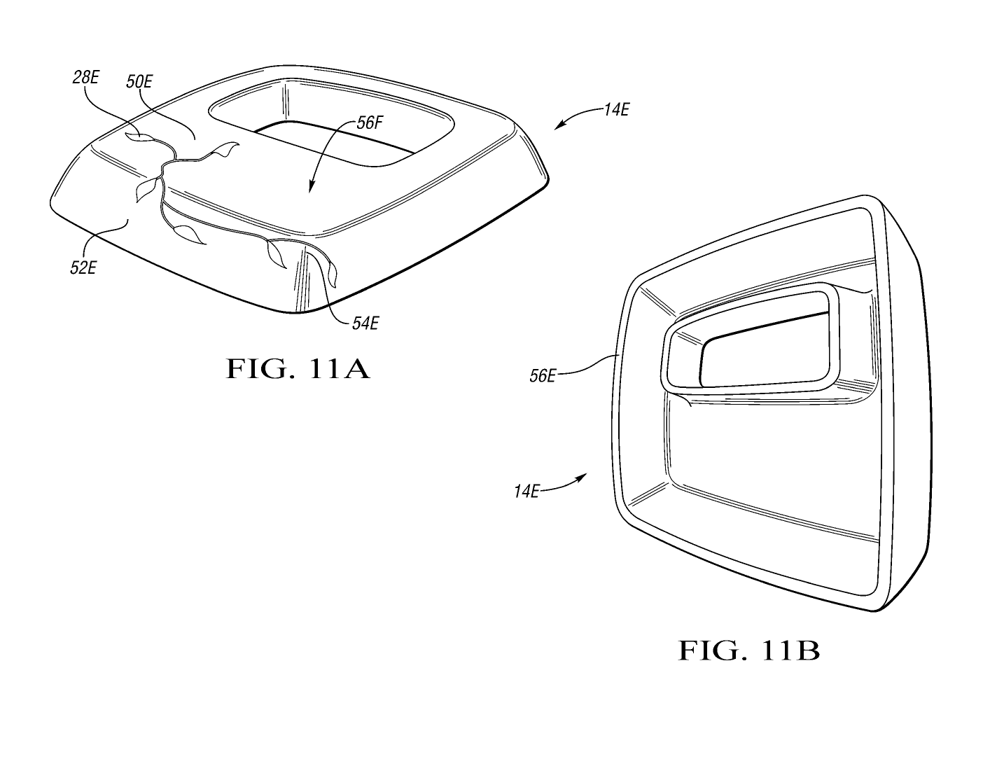

Referring to FIGS. 11A and 11B, another embodiment of a lighting display 14E is shown. The lighting display 14E may be manufactured according to any of the processes described with respect to FIGS. 3-10, so that it includes a lighting member, a substrate, and, optionally, a transparent layer if the lighting member is on the “A” surface of the substrate. An image 28E is apparent when the lighting member is activated. When assembled as shown, the various layered components of the lighting display 14E may be indistinguishable from one another. Because the lighting member is flexible, emitted light is apparent with uniform intensity on relatively flat portions 50E of the lighting display 14E, on curved portions 52E, and on contoured portions 54E. The lighting display 14E may be molded with extensions serving as connectors (not shown) that extend from an underside 56E of the display 14E to connect the display 14E to a mounting surface. The underside 56E may be a surface of the substrate, with the lighting member on an opposing side (i.e., an “A” surface 56F) of the display 14E. The light-emitting member thus need not be configured to emit light through the entire substrate, and thus may be of lower intensity to reduce the amount of energy required to produce the same visible luminosity.

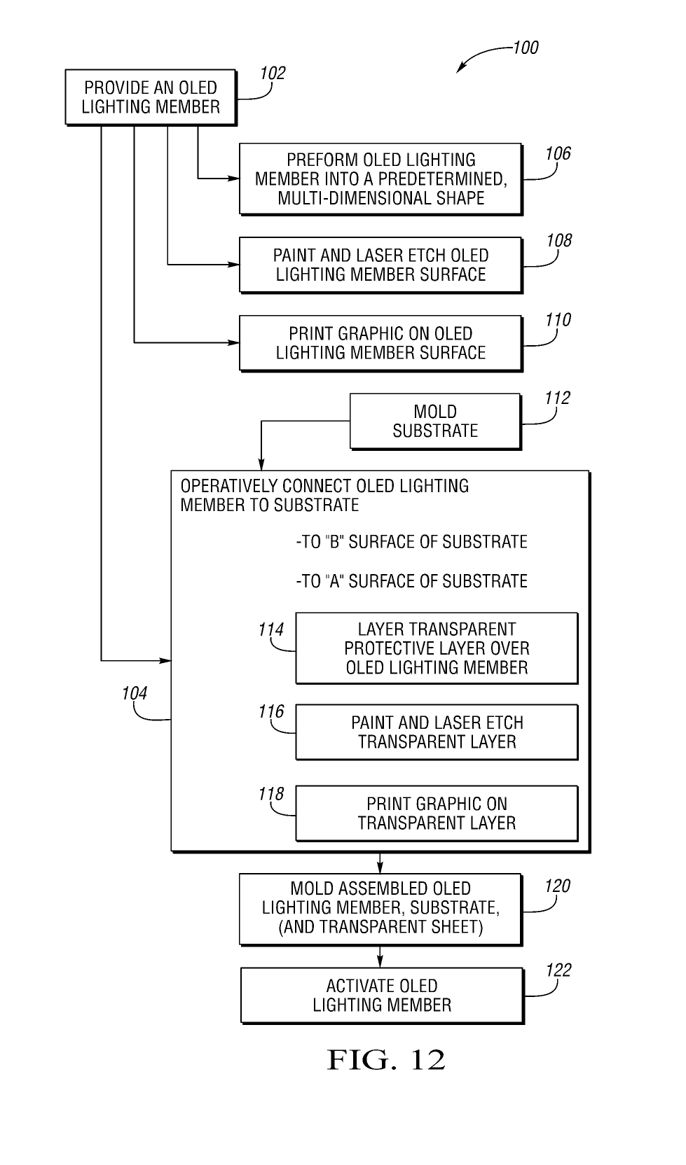

Referring to FIG. 12, a method 100 of manufacturing a lighting display is shown. The method 100 may be used to manufacture any of the lighting displays of FIGS. 1-11B, with some of the method steps being optional, and only applicable to some of the lighting display embodiments. The method 100 begins with block 102, in which a lighting member is provided. The lighting member may be an OLED member, such as lighting member 22A, 22B, 22C or 22D.

Depending on which lighting display 14-14E is being manufactured, the method 100 may proceed to optional blocks 106-110. In block 106, the OLED lighting member is preformed, such as by injection molding, into a predetermined, multi-dimensional shape. For example, lighting members 22B and 22D are preformed in this manner.

Next, an image may be applied to the lighting member according to either block 108 or 110. For example, in block 108, image 16 or 28A, 28B, 28C or 28D may be applied by painting and laser etching a surface of the lighting member. Alternatively, the image may be applied by printing a graphic on the surface of the lighting member in block 110.

Once the OLED lighting member has been subjected to any applicable ones of blocks 106, 108 and 110, it is operatively connected to a substrate 22A, 22B, 22C or 22D in block 104. The substrate may be pre-molded in block 112, such as is described with respect to substrates 20B and 20D. The connection of the OLED lighting member of block 102 to the substrate in block 104 may be at the “B” surface of the substrate, such as surface 24A or 24B in FIGS. 3 and 5. Alternately, the connection of the OLED lighting member to the substrate in block 104 may be to the “A” surface of the substrate, such as surface 26C or 26D in FIGS. 7 and 9.

A transparent layer may be applied over the OLED lighting member in block 114, such as transparent layer 40C or 40D of FIGS. 7 and 9. If a transparent layer is provided, the image may be provided on the transparent layer rather than on the lighting member by painting and etching the image on the surface of the transparent layer in block 116, or by printing a graphic on the transparent layer in block 118.

After the OLED lighting member and the substrate are connected, if these components are not already separately molded, e.g., the lighting member is not already preformed according to block 106 and the substrate molded according to block 112, then in block 120, the lighting member, substrate, and transparent sheet (if one is used in the lighting display) can be placed together into a common mold and molded. Finally, once the lighting display is completed, the lighting member can be activated in block 122 to provide a lighted static or dynamic image or video.

While the best modes for carrying out the invention have been described in detail, those familiar with the art to which this invention relates will recognize various alternative designs and embodiments for practicing the invention within the scope of the appended claims.

1. A lighting display comprising.
an organic light emitting diode (OLED) member activatable to emit light; and
a substrate adjacent the OLED member, the substrate and OLED cooperating to form an integral, multi-dimensional lighting display.

2. The lighting display of claim 1, further comprising:
a transparent member positioned on the OLED member so that the OLED member is between the transparent member and the substrate.

3. The lighting display of claim 1, wherein the OLED member has a surface with an image thereon; and wherein the image is more visible when the OLED member is activated to emit light than when the OLED member is not activated.

4. The lighting display of claim 3, wherein the OLED member is configured to be dynamically activatable so that a first portion of the image is visible prior to a second portion of the image.

5. The lighting display of claim 1, wherein the OLED member and the substrate are molded to have adjacent surfaces with complementary shapes so that the adjacent surfaces are in contact with one another substantially over the entirety of the adjacent surfaces.

6. The lighting display of claim 1, wherein the OLED member is positioned on a first side of the substrate such that light emitted from the OLED member is visible through the substrate on a second opposing side of the substrate.

7. A component for an automotive vehicle comprising:
a light-emitting member activatable to emit light and having a surface;
a substrate connected with the light-emitting member and having another surface in contact with the surface of the light-emitting member such that the substrate and the light-emitting member are coextensive; wherein the light-emitting member and the substrate together have a curved portion and a contoured portion; and
wherein the light-emitting member has an image that extends over the curved portion and the coextensive portion; and wherein the image is lighted when the light-emitting member is activated and areas of the light-emitting member surrounding the image are not lighted.

8. The component of claim 7, wherein the substrate is substantially transparent and is placed over the light-emitting member.

9. The component of claim 6, wherein the light-emitting member is configured to be dynamically activatable so that a first portion of the image is visible prior to a second portion of the image.

10. A method of manufacturing a lighting display comprising:
molding a substrate and an organic light emitting diode (OLED) member either separately or simultaneously; wherein the OLED member is activatable to emit light; and
operatively connecting the OLED member to the substrate to form an integral, multi-dimensional lighting display.

11. The method of claim 10, further comprising:
painting and laser etching the OLED member.

12. The method of claim 10, further comprising:
printing an image on the OLED member.

13. The method of claim 10, further comprising:
layering a transparent member over the OLED member so that the OLED member is between the transparent member and the substrate.

14. The method of claim 13, further comprising:
painting and laser etching the transparent member.

15. The method of claim 13, further comprising:
printing an image on the OLED member.
